(19) United States
(12) Patent Application Publication
(10) Pub. No.: US 2006/0175693 A1
(43) Pub. Date: Aug. 10, 2006

(54) Systems, methods, and apparatus for generating ball-out matrix configuration output for a flex circuit

(75) Inventors: James W. Cady, Austin, TX (US); Paul Goodwin, Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group, L.P.

(21) Appl. No.: 11/051,815

(22) Filed: Feb. 4, 2005

(51) Int. Cl. H01L 23/02

(52) U.S. Cl. 257/686

(57) ABSTRACT

Systems, methods, and apparatus for generating a ball-out matrix configuration for a flex circuit are provided. An exemplary processor implemented method for generating a ball-out matrix configuration for at least one flex circuit includes retrieving a set of ball-out matrix constraints for the flex circuit. The method further includes processing the set of ball-out matrix constraints to generate a ball-out matrix configuration output for the flex circuit.

### TECHNICAL FIELD

The present invention relates to aggregating integrated circuits and, in particular, to systems and methods for generating ball-out matrix configuration output for a flex circuit.

### BACKGROUND OF THE INVENTION

A variety of techniques are used to stack packaged integrated circuits. Some methods require special packages, while other techniques stack conventional packages. In some stacks, the leads of the packaged integrated circuits are used to create a stack, while in other systems, added structures such as rails provide all or part of the interconnection between packages. In still other techniques, flexible conductors with certain characteristics are used to selectively interconnect packaged integrated circuits.

The predominant package configuration employed during the past decade has encapsulated an integrated circuit (IC) in a plastic surround typically having a rectangular configuration. The enveloped integrated circuit is connected to the application environment through leads emergent from the edge periphery of the plastic encapsulation. Such “leaded packages” have been the constituent elements most commonly employed by techniques for stacking packaged integrated circuits.

Leaded packages play an important role in electronics, but efforts to miniaturize electronic components and assemblies have driven development of technologies that preserve circuit board surface area. Because leaded packages have leads emergent from peripheral sides of the package, leaded packages occupy more than a minimal amount of circuit board surface area. Consequently, alternatives to leaded packages known as chip-scale packaged (“CSP”) devices have recently gained market share.

CSP refers generally to packages that provide connection to an integrated circuit through a set of contacts (often embodied as “bumps” or “balls”) arrayed across a major surface of the package. Instead of leads emergent from a peripheral side of the package, contacts are placed on a major surface and typically emerge from the planar bottom surface of the package.

CSP has enabled reductions in size and weight parameters for many applications. For example, micro ball grid array for flash and SRAM and wirebond on tape or rigid laminate CSPs for SRAM or EEPROM have been employed in a variety of applications. CSP is a broad category including a variety of packages from near chip scale to die-sized packages such as the die sized ball grid array (DSBGA) recently described in proposed JEDEC standard 95-1 for DSBGA.

Generally, CSP devices are stacked into a two-high stack or a four-high stack by using flex circuits to interconnect the CSP devices. Stacking multiple CSP devices, however, raises significant issues. The previously known methods for stacking CSP devices have various deficiencies including complex structural arrangements and thermal or high frequency performance issues.

When stacking CSP devices, alignment between the flex circuit and a CSP device is required. Typically, flex circuits used for stacking CSPs have a completely filled in ball-out matrix. This configuration can cause problems when there is even a slight misalignment between the flex circuit and the CSP device.

Moreover, a flex circuit used in a stack of CSP devices must satisfy several constraints imposed by various factors, such as constraints related to the dimensions of the various elements of the stack. In particular, the combination of CSP devices of various sizes in a stack may result in dimension-related constraints on the flex circuit. Similarly, the stack may need to satisfy certain performance thresholds and requirements, which may impose additional constraints on the design of the flex circuit.

Traditional flex circuit design techniques have been either manual design or computer-aided design (CAD) using elementary package design tools, which may help a designer generate a layout for the flex circuit. Such tools, however, are inadequate, in that, among other limitations, they do not provide any means for addressing many issues raised by the use of flex circuits in a stack.

What is needed, therefore, are systems, methods, and apparatus for generating a ball-out matrix configuration output for a flex circuit.

### SUMMARY OF THE INVENTION

Consistent with the present invention, CSP devices may be stacked with greater ease. By way of a non-limiting example, a two-high CSP module may have two CSPs stacked, with one CSP disposed above the other. The two CSPs may be connected with one or a pair of flex circuits. The flex circuitry may be partially wrapped about a respective opposite lateral edge of the lower CSP of the stack. The flex circuitry may connect the upper and lower CSPs and provide a thermal and electrical path connection path between the stack and an application environment such as a printed wiring board (PWB).

In one embodiment of the invention, a module comprising a first CSP device and a second CSP device is provided. The module may comprise a flex circuit for interconnecting the first CSP device and the second CSP device using a flex circuit having a set of contacts that have some contacts removed thus allowing a tolerance zone where any misalignment is inconsequential. For example, at least one of a row of contacts, a column of contacts, or a set of diagonally arranged set of contacts out of the set of contacts may be omitted to facilitate connection between the first CSP device and the second CSP device or between a first CSP and the flex circuit.

In another embodiment of the invention, a processor implemented method for generating at least one ball-out matrix configuration for a flex circuit is provided. The method may include retrieving a set of ball-out matrix constraints from a database. The method may further include, using a processor, processing the set of ball-out matrix constraints to generate at least one ball-out matrix configuration output for the flex circuit.

In yet another embodiment of the invention, a processor implemented method for generating at least one ball-out matrix configuration for at least one flex circuit is provided. The method may include, for at least one flex circuit, retrieving a set of ball-out matrix constraints, including a subset of constraints related to a function performed by at least one of two CSP devices, a subset of constraints related to performance requirements associated with at least one the two CSP devices, and a subset related to interconnectivity requirements of at least one of two CSP devices to another device or module. The method may further include, using a processor, processing the set of ball-out matrix constraints to generate at least one ball-out matrix configuration output for the flex circuit.

In still another embodiment, a system for generating at least one ball-out matrix configuration for a flex circuit is provided. The system may include a memory comprising: (1) a file containing function derived constraints, (2) a file containing standard compliance derived constraints, and (3) a file containing interconnectivity derived constraints. The system may further include, a processor for executing a ball-out matrix configuration generator, which when executed, may process at least two of the file containing function derived constraints, the file containing standard compliance derived constraints, and the file containing interconnectivity derived constraints. Based on that, the processor may generate at least one ball-out matrix configuration output for the flex circuit.

### SUMMARY OF THE INVENTION

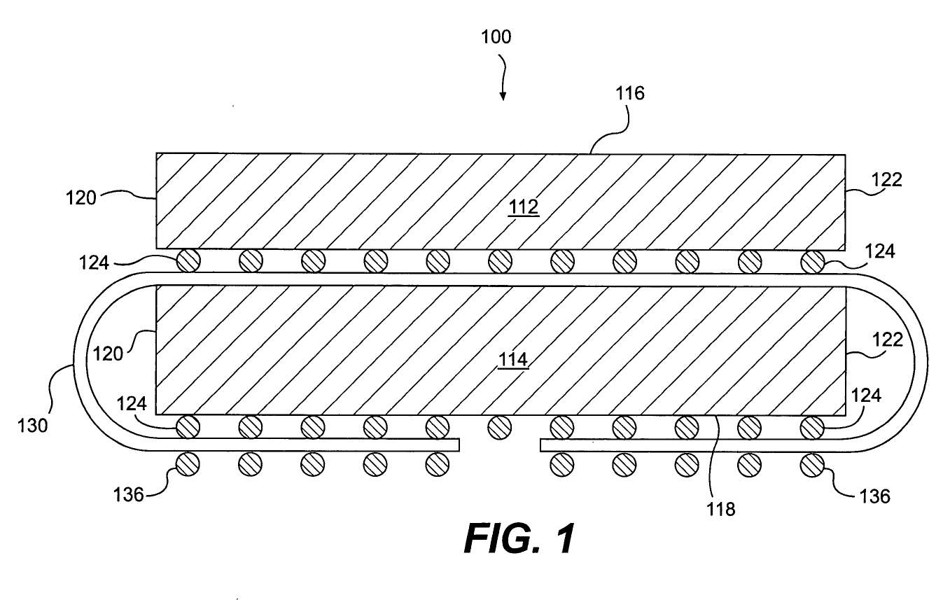

FIG. 1 is an elevation view of a high-density circuit module, consistent with one embodiment of the invention;

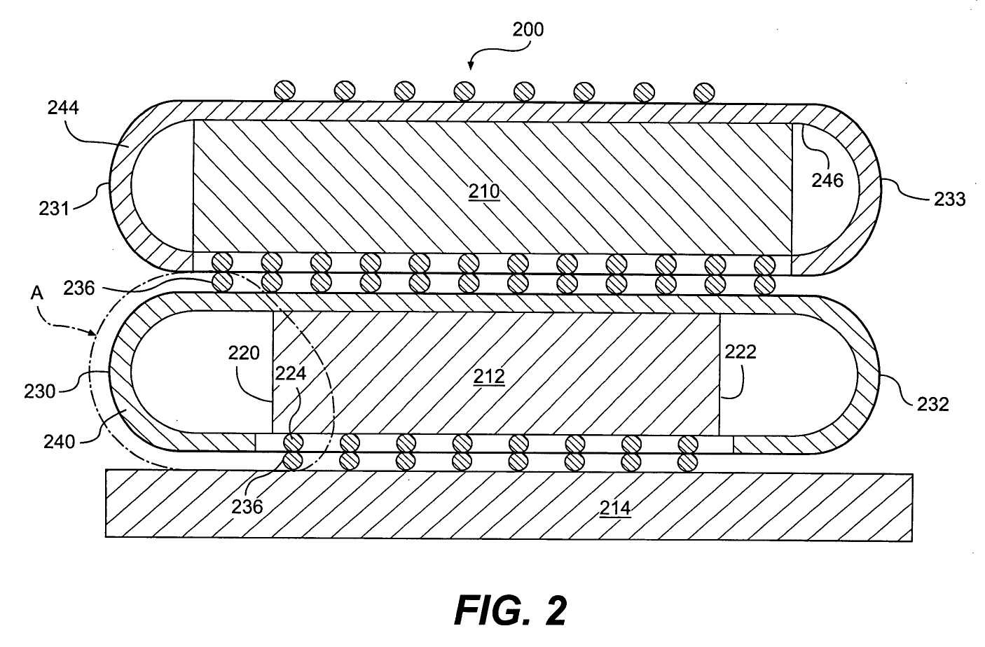

FIG. 2 is an elevation view of a stack, consistent with another embodiment of the invention;

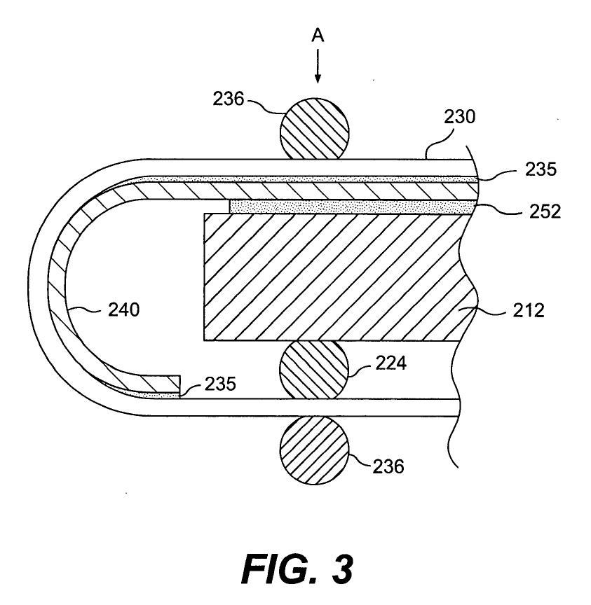

FIG. 3 depicts an enlarged view of the area marked “A” in FIG. 2;

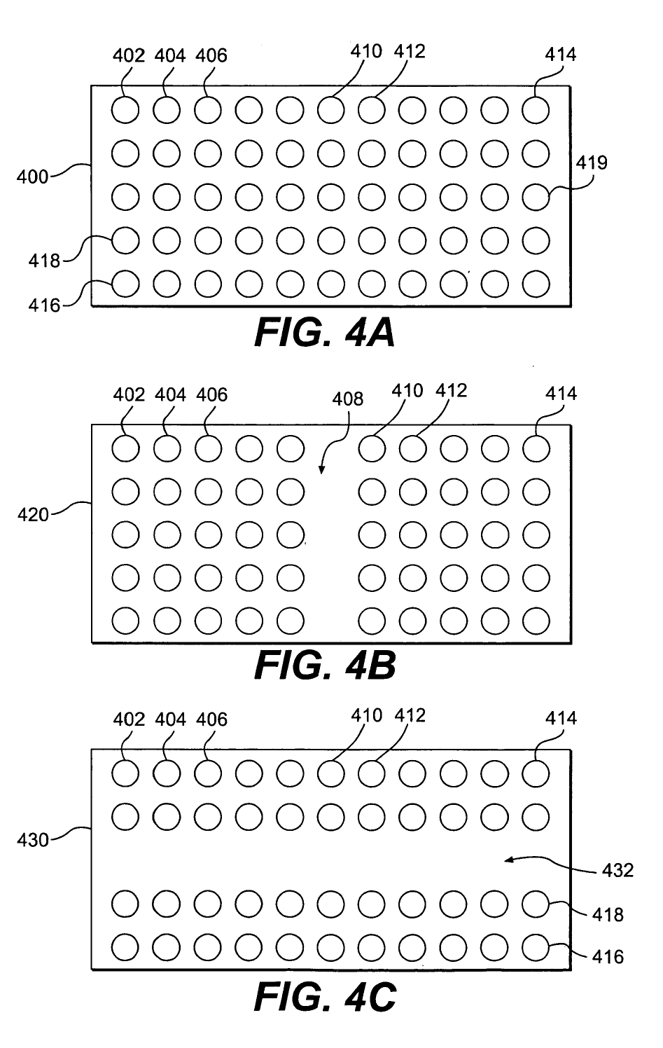

FIGS. 4A-C show a top view of exemplary flex circuit ball-out matrix configurations, consistent with another embodiment of the invention;

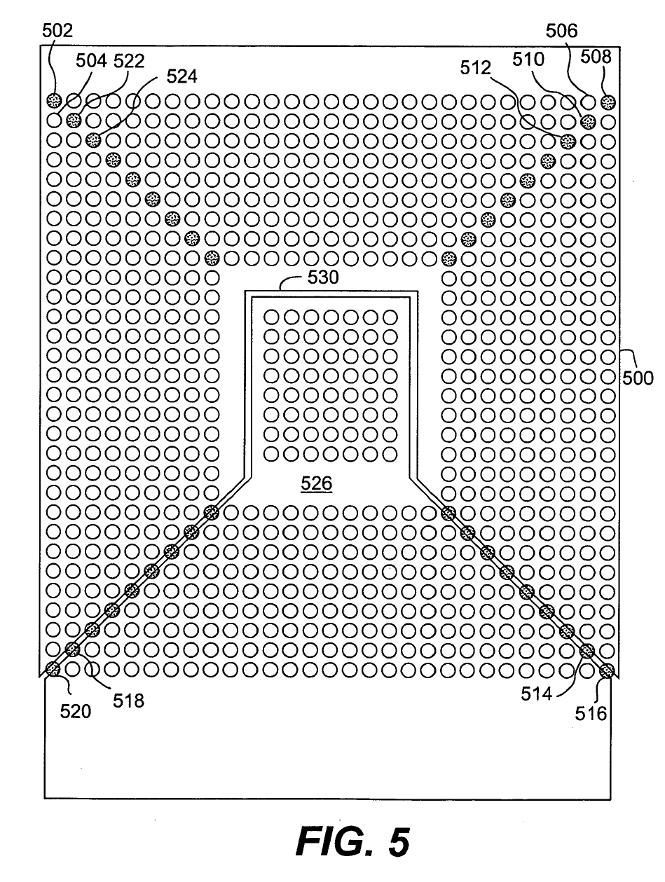

FIG. 5 shows a top view of another exemplary flex circuit ball-out matrix configuration, consistent with another embodiment of the invention;

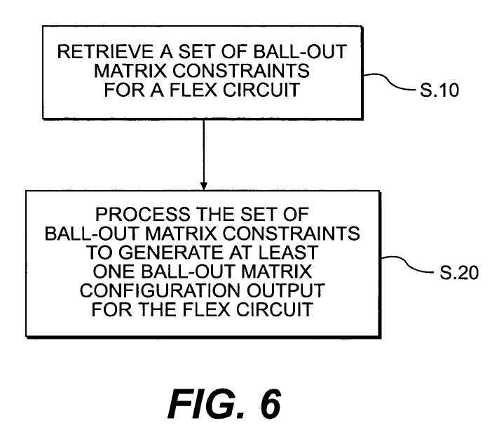

FIG. 6 is a flow chart of an exemplary method for generating a ball-out matrix configuration for a flex circuit, consistent with another embodiment of the invention;

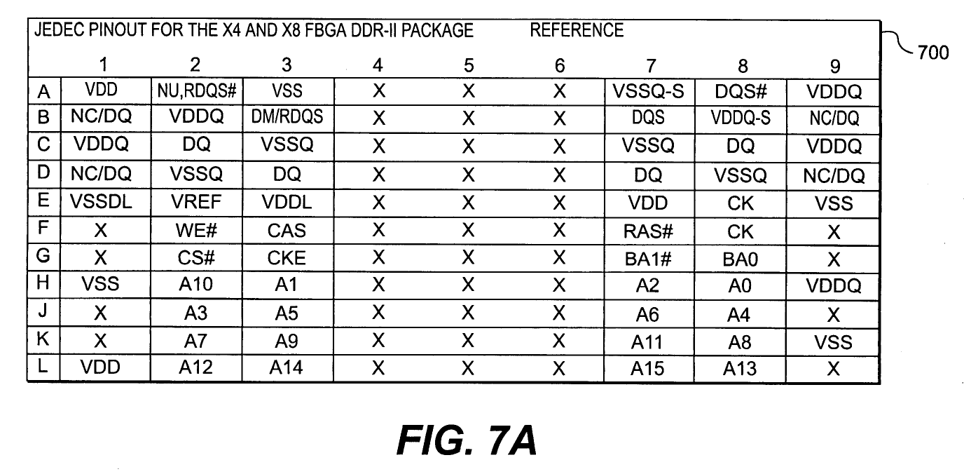

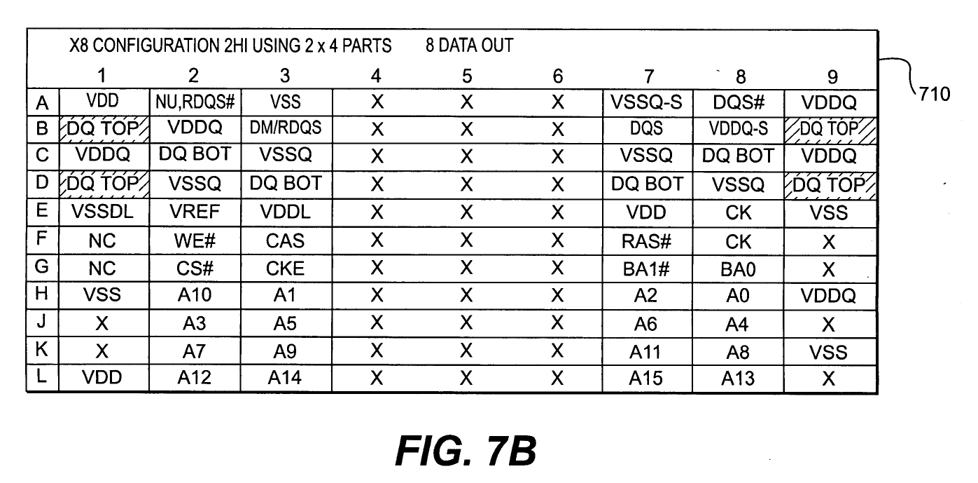

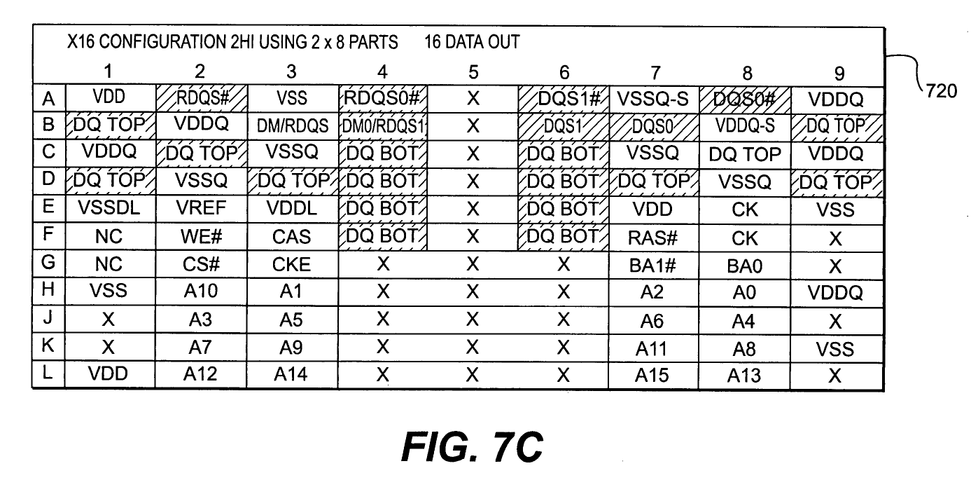

FIGS. 7A-7C depict exemplary module pinout, consistent with another embodiment of the invention;

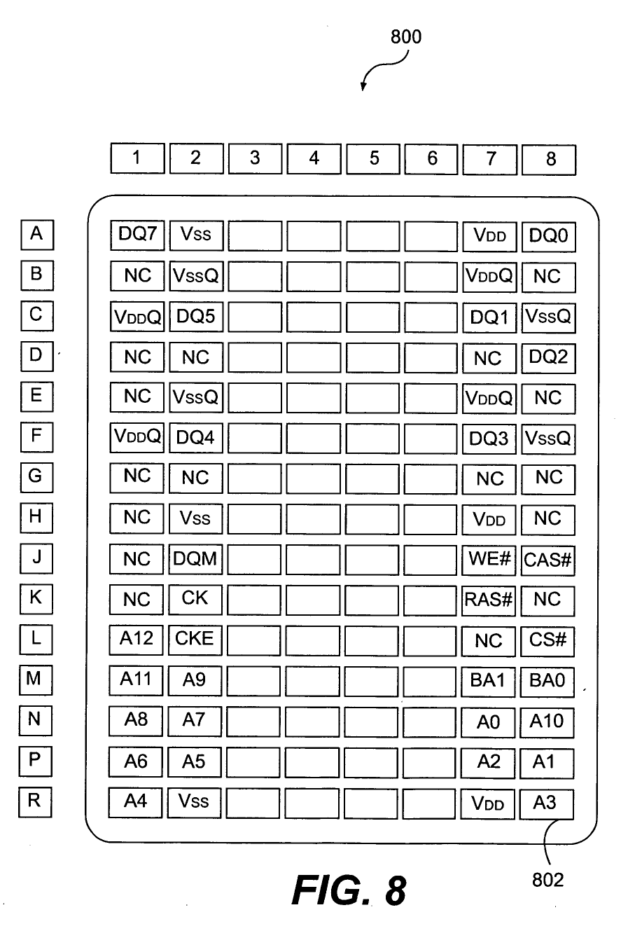

FIG. 8 depicts pinout of an exemplary CSP, consistent with another embodiment of the invention;

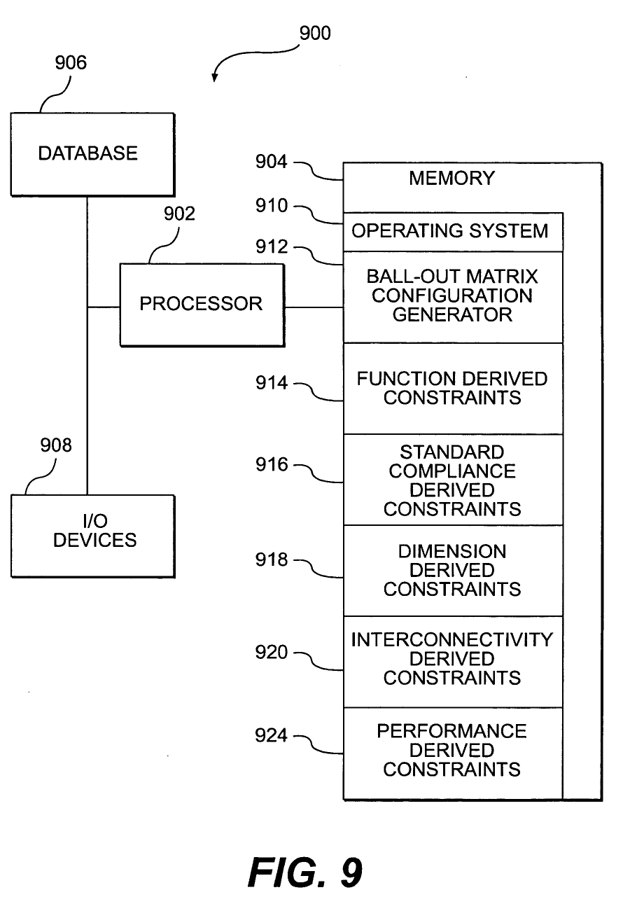

FIG. 9 depicts an exemplary system for generating a ball-out matrix configuration for a flex circuit, consistent with another embodiment of the invention;

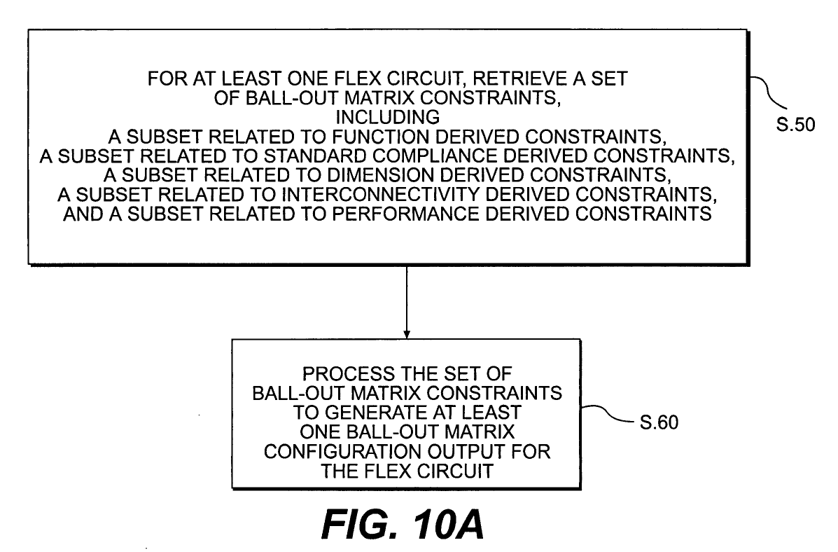

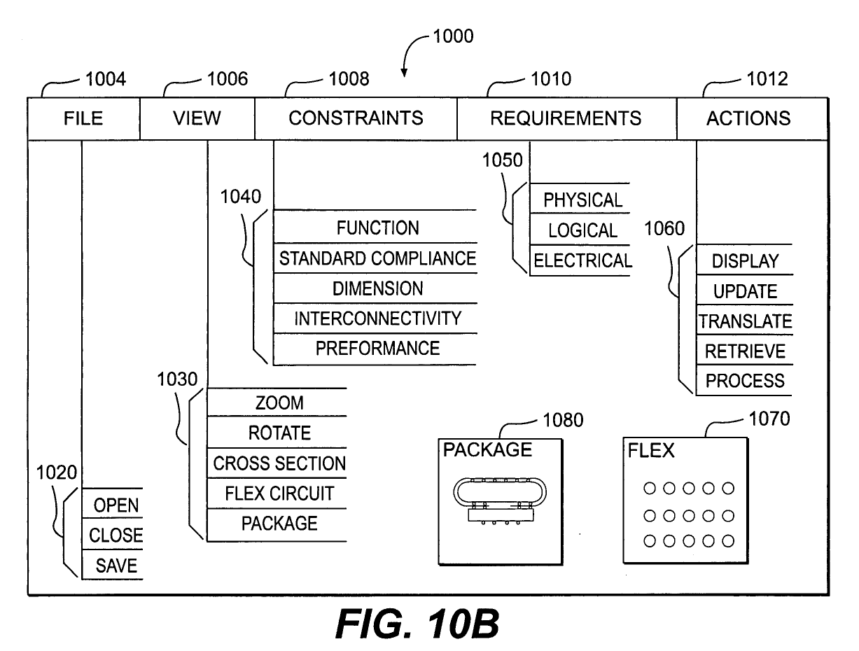

FIG. 10A is a flow chart for another exemplary method for generating a ball-out matrix configuration for a flex circuit, consistent with another embodiment of the invention; and

FIG. 10B is a drawing illustrating an exemplary user interface for generating a ball-out matrix configuration for a flex circuit, consistent with another embodiment of the invention.

### DESCRIPTION OF PREFERRED EMBODIMENTS

FIG. 1 is an elevation view of a module 100 devised in accordance with an embodiment of the present invention. Module 100 may comprise upper CSP 112 and a lower CSP 114. Each of CSPs 112 and 114 may have an upper surface 116 and a lower surface 118 and opposite lateral sides 120 and 122.

CSP packages of a variety of types and configurations such as, for example, those that are die-sized, as well those that are near chip-scale as well as the variety of ball grid array packages known in the art, may be used consistent with various embodiments of the invention. Collectively, these will be known herein as chip scale packaged integrated circuits (CSPs) and various embodiments will be described in terms of CSPs, but the particular configurations used in the explanatory figures are not, however, to be construed as limiting. By way of a non-limiting example, the elevation view of FIG. 1 corresponds to CSPs of a particular profile, but it should be understood that the figures are exemplary only. Embodiments of the invention may be employed to advantage in a wide range of CSP configurations available in the art where an array of connective elements is emergent from at least one major surface.

Typical CSPs, such as, for example, ball-grid-array (“BGA”), micro-ball-grid array, and fine-pitch ball grid array (“FBGA”) packages have an array of connective contacts embodied, for example, as leads, bumps, solder balls, or balls that extend from lower surface 118 of a plastic casing in any of several patterns and pitches. An external portion of the connective contacts is often finished with a ball of solder. Shown in FIG. 1 are CSP contacts 124 along lower surfaces 118 of CSPs 112 and 114. CSP contacts 124 provide connection to the integrated circuit within the respective packages.

In FIG. 1, a flex circuit (“flex”, “flex circuit” or “flexible circuit structure”) 130 is shown partially wrapped about lower CSP 114 with flex 130 partially wrapped over lateral side 120 of lower CSP 114 partially wrapped about lateral side 122 of lower CSP 114. Lateral sides 120 and 122 may be in the character of sides or may, if the CSP is especially thin, be in the character of an edge. Flex circuit 130 also includes module contacts 136, which may be used to connect the flex circuit to other CSP devices, modules, and/or an application environment, such as a PWB. Any flexible or conformable substrate with one or more conductive layer capability may be used as a flex circuit in the invention. The entire flex circuit may be flexible or, as those of skill in the art will recognize, a PCB structure made flexible in certain areas to allow conformability around lower CSP 114 and rigid in other areas for planarity along CSP surfaces may be employed as an alternative flex circuit in the present invention. For example, structures known as rigid-flex may be employed. Although FIG. 1 shows only one flex circuit 130, more than one flex circuit may be used consistent with the invention.

Portions of flex circuit 130 may be fixed to upper surface 116 of lower CSP 114 by an adhesive, such as a tape adhesive, which may be a liquid adhesive or may be placed in discrete locations across the package. Adhesive may be thermally conductive and adhesives that include a flux may be used.

Flex circuit 130 may, preferably, be a multi-layer flexible circuit structure that has at least two conductive layers. The conductive layers may be metal or alloy. A flex circuit may have a certain shape, for example, rectangular. The flex circuit may also be folded or bent based on the configuration selected for the flex circuit and a module that may be constructed.

FIG. 2 is an elevation view of a stack 200 consistent with another embodiment of the invention. FIG. 2 has an area marked “A” that is subsequently shown in enlarged depiction in FIG. 3. As shown in FIG. 2, a stack may include an upper CSP device 210 and a lower CSP device 212. Upper CSP device 210 may have a pair of flex circuits 231 and 233 at least partially wrapped around it. Lower CSP device 212 may have a pair of flex circuits 232 and 234 at least partially wrapped around it. Lower CSP device 212 may be connected via module contacts 236 to another device 214. Form standards 240 and 244 (explained later) may be used consistent with some aspects of the invention. Although FIG. 2 shows a stack with two devices connected to another device 214, stacks with additional CSP devices may be constructed consistent with the present invention. Further, a system stack comprising various CSP devices and/or stacks may be connected to an application environment such as a PWB.

FIG. 3 depicts in enlarged view, the area marked “A” in FIG. 2. FIG. 3 illustrates one arrangement of a form standard 240 and its relation to flex circuitry (230, 232) in a stack 200. Also shown are adhesives 235 between flex circuit (230, 232) and form standard 240. Although, adhesive 235 is not required, it is preferred and the site of its application may be determined as being best in the area between CSPs with a smaller amount near the terminal point of form standard 240 as shown in FIG. 3. Also shown in FIG. 3 is an application of adhesive 235 between form standard 240 and CSP 212.

A form standard 240 is shown disposed adjacent to upper surface 116 of CSP 232. Form standard 240 may be fixed to upper surface of the respective CSP with an adhesive, which may be thermally conductive. Form standard 240 may also, in alternative embodiments, merely lay on upper surface or be separated from upper surface by an air gap or medium such as a thermal slug or non-thermal layer.

Form standard 240 may be devised from copper to create a mandrel that mitigates thermal accumulation while providing a standard sized form about which flex circuitry is disposed. Form standard 240 may also be devised from nickel plated copper in preferred embodiments. Form standard 240 may take other shapes and forms such as, for example, an angular “cap” that rests upon the respective CSP body. It also need not be thermally enhancing although such attributes are preferable. The form standard 240 allows embodiments of the invention to be employed with CSPs of varying sizes, while articulating a single set of connective structures useable with the varying sizes of CSPs. Thus, a single set of connective structures such as flex circuits 230 and 232 (or a single flexible circuit in the mode where a single flex is used in place of the flex circuit pair 230 and 232) may be devised and used with the form standard 240 method and/or systems disclosed herein to create stacked modules with CSPs having different sized packages. This may allow the same flex circuitry set design to be employed to create iterations of a stacked module from constituent CSPs having a first arbitrary dimension X across attribute Y (where Y may be, for example, package width), as well as modules from constituent CSPs having a second arbitrary dimension X prime across that same attribute Y. Thus, CSPs of different sizes may be stacked into a module with the same set of connective structures (i.e., flex circuitry). Further, mixed sizes of CSPs may be implemented into the same module, such as would be useful to implement embodiments of a system-on-a-stack such as those disclosed in co-pending application PCT/US03/29000, filed Sep. 15, 2003, which is incorporated herein by reference and commonly owned by the assignee of the present application.

In one embodiment, portions of flex circuits 230 and 232 may be fixed to form standard 240 by bonds used for a flex reference which, are in some instances may be, metallurgical bonds created by placing on form standard 240, a first metal layer such as tin, for example, which, when melted, combines with a second metal that was placed on the flex circuitry or is part of the flex circuitry (such as the gold plating on a conductive layer of the flex) to form a higher melting point intermetallic bond that will not remelt during subsequent reflow operations as will be described further.

FIGS. 4A-C show a top view of exemplary ball-out matrix configurations, consistent with another embodiment of the invention. Those of skill will appreciate that these are just examples and in practice, the techniques of the present invention may result in ball-out matrix patterns that may not exhibit physical symmetry and that the patterns generated will be dictated by a variety of input constraints such as, for example, functionality of particular array contacts on the CSP to be stacked. FIG. 4A shows an exemplary ball-out matrix configuration 400 for a flex circuit. By way of a non-limiting example, ball-out matrix configuration may relate to a two-dimensional layout of bumps or balls (“referred to as balls”) on a flex circuit. The balls may be arranged in columns (402, 406, 406, 410, 412, and 414), and rows (416, 418, and 419). FIG. 4B shows another exemplary ball-out matrix configuration 420 in which a column 408 of balls has been omitted. FIG. 4C shows yet another exemplary ball-out matrix configuration 430 in which a row 432 of balls has been omitted. Instead of omitting the contacts, in one aspect of the invention, certain sets of balls may be left unconnected.

FIG. 5 shows a top view of another exemplary ball-out matrix configuration 500, consistent with another embodiment of the invention. By way of a non-limiting example, ball-out matrix configuration 500 shows balls arranged in rows (502 and 504) and columns (506 and 508) on a flex circuit. In one example, diagonally arranged balls (510, 512, 514, 516, 518, 520, 522, and 524) may be omitted from the flex circuit. Additionally and/or alternatively an area 526 may be devoid of any balls. Further, a cut 530 may be provided in the flex circuit so as to enable folding of the flex circuit. Consistent with the invention, other examples of layout may relate to the shape of the flex circuit as well (e.g. spherical, cubical, or other shapes).

FIG. 6 is a flow chart of an exemplary method for generating a ball-out matrix configuration for a flex circuit, consistent with another embodiment of the invention. The exemplary method may involve retrieving a set of ball-out matrix constraints for a flex circuit (step S.10). In one embodiment, this step may be performed using the exemplary system shown in FIG. 9. The term “ball-out matrix constraints” may include one or more of computer recognizable information that may be used to model user requirements and/or preferences associated with designing a flex circuit. By way of non-limiting example, such constraints may include physical, logical, and/or electrical constraints related to function, performance, standard compliance, and/or interconnectivity, and any combination thereof, and any other user requirements and/or preferences. In one embodiment, a constraint may even relate to information such as whether the system stack uses form standards (shown in FIGS. 2 and 3). By way of example, ball-out matrix constraints may include information such as nets, lists, and other information that may capture constraint related information associated with a particular flex circuit. Any suitable modeling technique associated with computer-aided design (CAD) tools may be used to generate the sets of ball-out matrix constraints. By way of a non-limiting example, Allegro®, a design tool available from Cadence Design Systems, Inc. of San Jose, Calif. may be used to generate some of the related constraints for a flex circuit.

The term “retrieving,” or any form thereof, refers to opening, accessing, obtaining, or otherwise making available information, such as constraints related information to a processor such that the processor may process the retrieved information. As used herein, the term “retrieving” further includes moving constraint related information from a random access memory, such as 904 (FIG. 9, explained later) to a processor's cache or register. The term retrieving also includes information input via means such as audio, text, code, or any other method of inputting information such that a processor (e.g. 902 of FIG. 9) may process the inputted information.

The exemplary method may further include processing the set of ball-out matrix constraint to generate at least one ball-out matrix configuration output for the flex circuit (step S.20). In one embodiment, this step may be performed using the system of FIG. 9. The term “generating,” or any form thereof, refers to the use of a processor to create, modify, or transmit, or otherwise output information that may be used consistent with various embodiments of the invention. Thus, for example, “generating” may include the indirect acts of providing access to hardware and/or software, or to at least one client side application and/or a server side application for causing the processor to generate a ball-out matrix configuration output. This may be accomplished by providing a user with software to aid the user in the “generate” process. Additionally and/or alternatively, generating may include a software creating, modifying, or transmitting ball-out matrix configuration output without any real-time user involvement. The output information may be in human readable form and/or in machine readable form. Machine readable output information may be output to a lithography system (directly or indirectly) to generate a flex circuit consistent with the present invention.

Physical, logical, and/or electrical requirements for a flex circuit may be derived from design requirements, such as package design issues and conformance to standards related issues. Certain system interconnection requirements, for example, may be imposed by module pinout requirements dictated either by a standard, by user preferences, or a combination thereof. By way of non-limiting examples, FIGS. 7A-7C depict exemplary module pinout, consistent with another embodiment of the invention. FIG. 7A illustrates a JEDEC pinout 700 for DDR-II FBGA packages. FIG. 7B illustrates a pinout 710 provided by module contacts of a module expressing an 8-bit wide datapath. An exemplar module may include an upper CSP 112 and lower CSP 114 (FIG. 1) that are DDR-II-compliant in timing, but each of which are only 4 bits wide in datapath. The exemplary module mapped in FIG. 7B expresses an 8-bit wide datapath. For example, FIG. 7B depicts DQ pins differentiated in source between upper CSP 112 (“top”) and lower CSP 114 (“BOT”) to aggregate to 8-bits. FIG. 7C illustrates a pinout 720 provided by module contacts of module expressing a 16-bit wide datapath. The wide datapath embodiment may be employed with any of a variety of CSPs available in the field and such CSPs need not be DDR compliant. Regardless, however, standards compliance related information and/or user preferences related information may be translated into constraints, which then may be processed. Translation of physical, logical, and/or electrical requirements for a flex circuit into constraints related information may be achieved manually or the process may be automated using CAD tools.

FIG. 8 depicts pinout of an exemplary CSP, consistent with another embodiment of the invention. FIG. 8 illustrates exemplary pinout 800 of a memory circuit provided as a CSP and useable in the present invention. Individual array positions are identified by the JEDEC convention of numbered columns and alphabetic rows. The central area (e.g., A3-A6; B3-B6; etc.) is unpopulated. CSP contacts are present at the locations that are identified by alpha-numeric identifiers such as, for example, A3 (802). FIG. 8 depicts a metal layer of a flex circuit in an alternative embodiment of the invention in which a module expresses a datapath wider than that expressed by either of the constituent CSPs 112 and 114 of FIG. 1, for example. Lower flex contacts are not contacted by CSP contacts of lower CSP 114, but are contacted by module contacts to provide, with selected module contacts, a datapath for the module 10 that is 2n-bits in width where the datapaths of CSPs 112 and 114 have a width of n-bits. Although FIGS. 7A-C and 8 illustrate circuit layout constraints, other constraints on system design may be expressed and stored in files or other repositories of information, consistent with the invention.

FIG. 9 depicts an exemplary system for generating a ball-out matrix configuration for a flex circuit, consistent with another embodiment of the invention. As shown in FIG. 9, an exemplary system 900 for generating a ball-out matrix configuration for a flex circuit may include a processor 902, a memory 904, a database 906, and I/O devices 908. System 900 may be implemented using a stand-alone user computer or it may be implemented using client-server architecture along with a network (e.g. the Internet). Thus, for example each of the components shown in FIG. 9, including both hardware and software components, may be distributed in any fashion over a network. Any network capable of transmitting information may be used consistent with embodiments of the invention. Memory 904 may further include an operating system 910, a ball-out matrix configuration generator 912 and information related to constraints, such as function derived constrains 914, standard compliance derived constraints 916, dimension derived constraints 918, interconnectivity derived constraints 920, and performance derived constraints 924. For clarity of explanation, the functionality of the mechanisms described herein is distinguished. However, it is to be understood that, in operation, the functionality of these mechanisms may differ from what is described. For example, the mechanisms may be separate, each residing at different locations, or they may be integrated into one software package residing at a common location. Thus, the mechanism for generating a ball-out matrix configuration output may be located on a client side, while the processing mechanism may reside on a server side.

FIG. 10A is a flow chart for another exemplary method for generating a ball-out matrix configuration for a flex circuit, consistent with another embodiment of the invention. The exemplary method may include for at least one flex circuit, retrieving a set of ball-out matrix constraints, including a subset related to function derived constraints, a subset related to standard compliance derived constraints, a subset related to dimension derived constraints, a subset of interconnectivity derived constraints, a subset related to performance derived constraints (step S.50). As explained above, this step may be performed using the exemplary system of FIG. 9.

The exemplary method may further include processing the set of ball-out matrix constraints to generate at least one ball-out matrix configuration output for the flex circuit (step S.60). As explained above, this step may be performed using the system of FIG. 9.

FIG. 10B is a drawing illustrating an exemplary user interface 1000 for generating a ball-out matrix configuration for a flex circuit, consistent with another embodiment of the invention. Exemplary user interface 1000 may include buttons, pull down menus, or other user interface elements to enable a user to execute a process associated with generating a ball-out configuration matrix output. Thus, for example, user interface 1000 may include pull-down lists allocated with higher-level functionality related to operating a software corresponding to the processes described herein. Exemplary pull-down lists may include options related to buttons, such as File 1004, View 1006, Constraints 1008, Requirements 1010, and Actions 1012. Selecting File 1004 button may present a user with options such as open, close, and/or save (1020). Selecting View 1006 button may present a user with options, such as zoom, rotate, cross section, flex circuit, and/or package (1030). Selecting Constraints 1008 button may present a user with options, such as function, standard compliance, dimension, interconnectivity, and/or performance (1040). Selecting Requirements 1010 button may present a user with options, such as physical, logical, and/or electrical (1050). Finally, selecting Actions 1012 may result in presentation of options, such as display, update, translate, retrieve, and process (1010). Also shown in FIG. 10B are exemplary views of a package 1080 and a flex circuit 1070. Using the exemplary user interface of FIG. 10B, a user may perform at least some aspects of the processes described herein.

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A circuit module comprising:
a first CSP device and a second CSP device, the first CSP device having a contact array that expresses a set of active contacts arranged in a selected pattern;
a flex circuit for interconnection to the first CSP device, the flex circuit having a selected array of contacts arranged in a flex circuit pattern that is made non-uniform by the omission of what would have been at least one of a row of contacts, a column of contacts, and a set of diagonally arranged contacts in the selected array of contacts thus causing the selected array of contacts of the flex circuit to electrically coincide with the set of active contacts of the first CSP device.

2. The module of claim 1 in which the flex circuit further comprises a cut in the flex circuit.

3. The module of claim 1 in which the flex circuit further comprises an area devoid of the set of contacts.

4. The module of claim 1 in which the flex circuit is configured to leave a subset of the set of contacts unconnected.

5. A processor implemented method for generating at least one ball-out matrix configuration for a flex circuit, adapted for use with a pair of CSP devices to form a high-density circuit module, the method comprising:
retrieving a set of ball-out matrix constraints from a database; and
using a processor, processing the set of ball-out matrix constraints to generate at least one ball-out matrix configuration output for the flex circuit, such that the ball-out matrix configuration includes an output corresponding to interconnection requirements between at least the pair of CSP devices.

6. The method of claim 5 in which the set of ball-out matrix constraints comprises a set of constraints related to compliance with requirements imposed by at least one standard on at least one of the pair of CSP devices.

7. The method of claim 5 in which the set of ball-out matrix constraints comprises a set of constraints related to dimensions of at least one of the pair of CSP devices.

8. The method of claim 5 in which the set of ball-out matrix constraints comprises a set of constraints related to interconnectivity requirements of at least one of the pair of CSP devices to another device or module.

9. The method of claim 5 in which the set of ball-out matrix constraints comprises a set of constraints related to a function performed by at least one of the pair of CSP devices.

10. The method of claim 5 in which the set of ball-out matrix constraints comprises a set of constraints related to a performance requirement of at least one of the pair of CSP devices.

11. The method of claim 6 in which the at least one standard is the JEDEC standard.

12. The method of claim 7 in which the dimensions of at least one of the pair of CSP devices comprise at least one of a length, a width, and a height.

13. The method of claim 8 in which the interconnectivity requirements of at least one of the pair of CSP devices comprise at least one of a physical, a logical, and an electrical interconnection requirement.

14. The method of claim 9 in which the function performed by at least one of the pair of CSP devices comprises at least one of a memory function, a processor function, a communications function, and any combination thereof.

15. A system for generating at least one ball-out matrix configuration for at least one flex circuit, adapted for use with a pair of CSP devices to form a high-density circuit module, the system comprising:
means for retrieving a set of ball-out matrix constraints from a database; and
means for processing the set of ball-out matrix constraints to generate at least one ball-out matrix configuration output for the flex circuit, such that the ball-out matrix configuration includes an output corresponding to interconnection requirements between at least the pair of CSP devices.

16. The system of claim 15 in which the set of ball-out matrix constraints comprises a set of constraints related to compliance with requirements imposed by at least one standard on at least one of the pair of CSP devices.

17. The system of claim 15 in which the set of ball-out matrix constraints comprises a set of constraints related to dimensions of at least one of the pair of CSP devices.

18. The system of claim 15 in which the set of ball-out matrix constraints comprises a set of constraints related to interconnectivity requirements of at least one of the pair of CSP devices to another device or module.

19. The system of claim 15 in which the set of ball-out matrix constraints comprises a set of constraints related to a function performed by at least one of the pair of CSP devices.

20. The system of claim 15 in which the set of ball-out matrix constraints comprises a set of constraints related to a performance requirement of at least one of the pair of CSP devices.

21. The system of claim 16 in which the at least one standard is the JEDEC standard.

22. The system of claim 17 in which the dimensions of at least one of the pair of CSP devices comprise at least one of a length, a width, and a height.

23. The system of claim 18 in which the interconnectivity requirements of at least one of the pair of CSP devices comprise at least one of a physical, a logical, and an electrical interconnection requirement.

24. The system of claim 19 in which the function performed by at least one of the pair of CSP devices comprises at least one of a memory function, a processor function, a communications function, and any combination thereof.

25. A processor implemented method for generating at least one ball-out matrix configuration for at least one flex circuit adapted for use with a pair of CSP devices to form a high-density circuit module, the method comprising:
for at least one flex circuit, retrieving a set of ball-out matrix constraints, including a subset of constraints related to a function performed by at least one of the pair of CSP devices, a subset of constraints related to performance requirements associated with at least one of the pair of CSP devices, and a subset related to interconnectivity requirements of at least one of the pair of CSP devices to another device or module; and
using a processor, processing the set of ball-out matrix constraints to generate at least one ball-out matrix configuration for the flex circuit.

26. The method of claim 25 in which the set of ball-out matrix constraints further comprises a subset of constraints related to compliance with requirements imposed by at least one standard on at least one of the pair of CSP devices.

27. The method of claim 25 in which the set of ball-out matrix constraints further comprises a subset of constraints related to dimensions of at least one of the pair of CSP devices.

28. The method of claim 26 in which the at least one standard is the JEDEC standard.

29. The method of claim 27 in which the dimensions of at least one of the pair of CSP devices comprise at least one of a length, a width, and a height.

30. The method of claim 28 in which the interconnectivity requirements of at least one of the pair of CSP devices comprise at least one of a physical, a logical, and an electrical interconnection requirement.

31. The method of claim 29 in which the function performed by at least one of the pair of CSP devices comprises at least one of a memory function, a processor function, a communications function, and any combination thereof.

32. For execution on a processor, a ball-out matrix generator user interface (UI) executing on the processor to present a user interface to enable a user to retrieve a set of ball-out matrix constraints related to at least one flex circuit used for interconnecting a pair of CSP devices and to enable the user to process the set of ball-out matrix constraints such that the processor may generate at least one ball-out matrix configuration output for the flex circuit, such that the ball-out matrix configuration output includes an output corresponding to interconnection requirements between the at least one of the pair of CSP devices and another module or device.
